(19) United States
(12) Patent Application Publication
(10) Pub. No.: US 2025/0185518 A1
(43) Pub. Date: Jun. 5, 2025

(54) METHOD FOR MANUFACTURING A SPIN-ORBIT TORQUE EFFECT MEMORY

(71) Applicants: COMMISSARIAT A L'ENERGIE ATOMIQUE ET AUX ENERGIES ALTERNATIVES, PARIS (FR); UNIVERSITE GRENOBLE ALPES, SAINT MARTIN D'HERES (FR); CENTRE NATIONAL DE LA RECHERCHE SCIENTIFIQUE, PARIS (FR); INSTITUT POLYTECHNIQUE DE GRENOBLE, GRENOBLE (FR)

(72) Inventors: Bernard VIALA, GRENOBLE CEDEX 09 (FR); Kévin GARELLO, GRENOBLE CEDEX 09 (FR); Louis HUTIN, GRENOBLE CEDEX 09 (FR); Bertrand DELAET, GRENOBLE CEDEX 09 (FR); Marco BIAGI, FIRENZE (IT)

(21) Appl. No.: 18/968,165

(22) Filed: Dec. 4, 2024

(30) Foreign Application Priority Data
Dec. 4, 2023 (FR) 2313524

(51) Int. Cl. H10N 50/10; H10N 50/01; H10N 50/20; H10N 50/80

(52) U.S. Cl. CPC H10N 50/10; H10N 50/01; H10N 50/20; H10N 50/80

(57) ABSTRACT

A method for manufacturing a spin-orbit torque effect memory, referred to as SOT memory, which is simple to execute and which offers a memory with a switching efficiency at least equivalent to the SOT memories of prior art. For this, the manufacturing method includes depositing a conductive layer, referred to as a spacer, onto a magnetic stack; etching the magnetic stack using the spacer as an etching mask so as to form a magnetic tunnel junction; and forming an SOT track on the spacer.

### CROSS-REFERENCE TO RELATED APPLICATIONS

This application claims priority to French Patent Application No. 2313524, filed Dec. 4, 2023, the entire content of which is incorporated herein by reference in its entirety.

### FIELD

The technical field of the invention is that of data storage in a memory, and more particularly a non-volatile magnetic memory using the Spin-Orbit Torque (SOT) effect.

### BACKGROUND

Non-volatile magnetic memories use for example a Magnetic Tunnel Junction (MTJ) consisting of two magnetic layers separated by a non-magnetic insulating layer. One of the magnetic layers is referred to as a “trapped layer” or “reference layer” because it exhibits a fixed magnetisation. The other magnetic layer is referred to as a “free layer” or “storage layer” because it exhibits a variable magnetisation that can take on distinct values or orientations. The non-magnetic insulating layer is so-called a “tunnel barrier” because it acts as a tunnel barrier during electron transport between both magnetic layers. The relative orientation of magnetisation of the free layer with respect to magnetisation of the reference layer enables information to be stored. The difference in resistance of the tunnel junction enables the stored information (i.e. the orientation of one magnetisation relative to the other) to be read. For example, a parallel configuration of magnetisations corresponds to a state of minimum electrical resistance and, for example, a low state, i.e. a data bit 0. The anti-parallel configuration of the magnetisations corresponds to a state of maximum resistance and, for example, a high state, i.e. a data bit 1. The relative difference is expressed as a percentage of Tunnel MagnetoResistance (TMR), which is usually in the order of 100% to 150% for conventional so-called “top pinned” junctions and in the order of 150% to 200% for conventional so-called “bottom pinned” junctions. The trapped and free layers most often have magnetisation orientations which are perpendicular to the plane of the layers. This is referred to as a perpendicular Magnetic Tunnel Junction (pMTJ).

A first generation of magnetic memories relies on a Spin Transfer Torque (STT) effect to modify orientation of the magnetisation of the free layer and write a specific state in the tunnel junction. Spin transfer torque is based on the flow of an electric current passing through the tunnel junction. The tunnel junction is therefore usually connected to two terminals.

A second generation of magnetic memories is based on the Spin-Orbit Torque (SOT) effect. An SOT memory comprises, in addition to the tunnel junction, a writing track also referred to as a “SOT track”, usually made of a heavy transition metal such as Pt or β-W. The SOT effect is a phenomenon that enables torque to be transmitted at an interface. The SOT track is therefore disposed directly in contact with the free layer of the tunnel junction. An electric current flowing in the SOT track, and not through the tunnel junction, generates a spin current (different from an electron current) which can exert torque on the magnetisation of the free layer and perform writing of a state. The SOT effect offers the advantage of separating current circulation paths to perform reading (flowing through the tunnel junction) and writing a state in the tunnel junction (flowing only in the SOT track). Tunnel junctions carried out by SOT require three terminals. Two of these connect the SOT track, to perform writing, and a third connects the tunnel junction, opposite to the SOT track, to perform reading of the junction state.

Although less compact than STT memories, SOT memories offer greater endurance because the write electric current only passes through the SOT track and no longer through the tunnel barrier (the latter has only the read current, which is always lower than the write current, passing therethrough). They can also be faster because their write time using the SOT effect can be shorter (between 0.3 ns and 1 ms) than that accessible using the STT effect (between 10 ns and 100 ns). Finally, SOT memories have better energy performance (in terms of power consumption per junction). These advantages mean that SOT memories, and the random access memories derived therefrom (referred to as “SOT-MRAM” for “SOT Magnetic Random Access Memory”), are used for embedded or “cache” type applications (memory that a microprocessor accesses more quickly and more frequently during calculations). For example, SOT-MRAMs are intended to replace static random access memories such as embedded SRAMs, which currently have no alternative. However, methods for manufacturing SOT memories and SOT-MRAMs are more complex and have not yet been fully mastered.

One of the problems to be solved is to make the SOT track and the junction by a method which should preserve integrity of the thin layers making up both elements and in particular the interface between the SOT track and the free layer. Indeed, SOT writing generally requires direct contact between the free layer and the SOT track without degrading the interface.

Document US 2020/013602 A1 discloses an alternating magnetic device comprising a magnetic element and an SOT track that are not in direct contact. This device comprises a metal spacer separating the SOT track and the magnetic element, having a high spin diffusion length and conductivity. The spacer thus makes it possible to collect and diffuse the spin current generated by the SOT track towards the magnetic element. The spacer has the particular feature of having a larger area than the area of the magnetic element, so as to form a funnel for spin currents from the SOT track.

Manufacturing this device comprises depositing all the layers required to make the SOT track firstly and the spacer secondly. The spacer is then delimited by anisotropic etching with stopping on the layer of SOT material. The SOT track is delimited by a second etching through a second hard mask. The mask used to delimit the spacer is then necessarily removed before depositing and delimiting the magnetic element.

Stopping etching of the spacer is a critical step and poor control of this stopping can damage the SOT track. Indeed, the SOT track can be a few tens of nanometres or even just a few nanometres thick. It can therefore be easily severed, rendering the device unusable. This method also requires two etching steps.

Application US 2017/0117323 A1 describes a method for manufacturing an SOT memory, for solving the risk of severing the SOT track when delimiting the tunnel junction by etching while maintaining a good quality interface between the free layer and the SOT track. To achieve this, it is suggested reversing the order of the layers so as to firstly deposit and delimit the tunnel junction and secondly deposit and delimit the SOT track. The SOT memory is “bottom-pinned”, i.e. the free layer is disposed at the head of the junction, so as to be in contact with the SOT layer. If delimitation of the tunnel junction no longer poses a risk to the SOT track, it requires forming a transition layer of SOT material, in contact with the free layer and before delimitation of the tunnel junction. Thus the transition layer protects the interface with the free layer during delimitation of the tunnel junction and allows the SOT track to be re-contacted. The transition layer and the tunnel junction are delimited using the same hard mask, which is then necessarily removed.

The SOT track is therefore in contact with the free layer via the transition layer. However, even though the transition layer is made of SOT material, it still reduces writing efficiency because the shape of the electric current lines flowing in the transition layer reduces efficiency of spin current generation. In addition, the transition layer is disposed in the current circulation path during upon reading. The junction may therefore have a higher total resistance and may have a reduced reading rate.

Application US 2018/0123031 A1 describes a method similar to that set out above. However, unlike the above method, recontacting the tunnel junction is made, not by the SOT track itself, but by a conductive track which connects the transition layer. The role of the SOT track is thereby ensured by the transition layer of SOT material. The transition layer and the tunnel junction are delimited using a same hard mask, which is then necessarily removed.

However, to maintain good writing efficiency, the conductive track should not short-circuit the transition layer. This requires etching the conductive track to remove the portions that could induce short-circuit. Formation of the conductive track that connects the transition layer is therefore complex to achieve and presents a risk for the memory not to properly operate.

There is therefore a need to provide a method for manufacturing a SOT memory which is simpler to execute and which provides a memory with a switching efficiency at least equivalent to SOT memories of prior art (i.e. having an interface at which the SOT effect is maximised).

### SUMMARY

To this end, the invention relates to a method for manufacturing a spin-orbit torque memory, referred to as an “SOT memory”, comprising, starting from a substrate, the following steps of:
depositing a magnetic stack for forming, after delimitation, a magnetic tunnel junction, the magnetic stack comprising a first magnetic layer exhibiting, after delimitation, a free magnetisation;
depositing a conductive layer onto the magnetic stack and directly against the first magnetic layer, the conductive layer having a spin diffusion length;
anisotropically etching a spacer into the conductive layer through a first etching mask with stopping on the magnetic stack;
etching the magnetic stack so as to delimit the magnetic tunnel junction, etching being carried out anisotropically employing the spacer as a second etching mask, the spacer exhibiting, after etching, a final thickness less than its spin diffusion length; and
forming, on and directly against the spacer, a so-called “SOT track” from a material exhibiting spin-orbit coupling.

By “conductive layer”, it is meant a layer with an electrical conductivity greater than 10⁶ S/m under standard conditions.

By “deposited directly against the first magnetic layer”, it is meant deposited into contact with this first magnetic layer, without an intermediate layer.

By “thickness of a layer”, it is meant a dimension of the layer measured perpendicularly to the substrate.

By “track”, it is meant a layer having a length and a width, measured in parallel to the substrate, its length being greater than its width.

This method makes it possible to form a memory point comprising a magnetic tunnel junction and an SOT track separated by a spacer. After delimiting the magnetic tunnel junction using the spacer as a second etching mask, the first magnetic layer forms a magnetic layer, referred to as a “free layer”, having a so-called “free” magnetisation, switchable between at least two distinct configurations. The spacer is in direct contact with the free layer. A current flowing in the SOT track makes it possible to create a spin accumulation at the surface of the SOT track. This accumulation makes it possible to generate a spin current in the spacer, which is in contact with the SOT track. The spacer allows this spin current to propagate towards the tunnel junction and more particularly into the free layer. Since the length of spin diffusion is greater than the distance separating the SOT track from the tunnel junction, a significant part of the spin current reaches the tunnel junction. This spin current can therefore exert a spin-orbit torque at the interface between the free magnetisation and the spacer. This spin current enables a state to be written to memory. The spacer therefore makes it possible to relocate the spin-orbit torque effect from the SOT track.

The interface at which the SOT effect is achieved is the interface of the free layer receiving the spin current, i.e. the interface shared by the tunnel junction and the spacer. After being deposited onto the first magnetic layer, the spacer can therefore protect the interface of this first magnetic layer at which the spin-orbit torque is exerted. In this way, this interface retains optimum quality, whatever subsequent manufacturing steps are implemented, for example to form the SOT track or conductive terminals.

In addition, the distance offered by the spacer allows stress relief on the manufacture of the SOT track. For example, it is possible to resort to materials whose manufacturing methods are not compatible with those of a magnetic layer or a magnetic tunnel junction in close proximity thereto. The SOT track can also be made secondly, without having to worry about degrading the interface between the tunnel junction and the spacer.

The final thickness of the spacer is only restricted by its spin diffusion length, which imposes a maximum final thickness. The spacer can thereby undergo aggressive manufacturing steps, such as polishing or etching, to obtain a suitably shaped SOT track.

At the end of the step of delimiting the tunnel junction, said tunnel junction and the spacer are delimited by one and the same flank.

By a material exhibiting spin-orbit coupling, it is meant a material which generates a flow-through spin current when it is traversed by a longitudinal electric current of electric charges. The charge-spin conversion efficiency is given per unit current (dimensionless). For materials with “strong spin-orbit coupling”, the efficiency is, in an embodiment, greater than 0.1, or even greater than 1 or, even greater than 50.

Beneficially, the conductive layer has an initial thickness h70 given by:

$$h 70 < h {10}^{′} \times v 30 / v {10}^{′} + δ$$

where h10′ is the thickness of the magnetic stack, v10′ is the etch rate of the magnetic stack, v30 is the etch rate of the conductive layer and δ is the spin diffusion length of the conductive layer, the etch rates of the magnetic stack and the conductive layer being considered for identical etching conditions. In this way, the final thickness of the spacer ensures the propagation of the spin current generated by the SOT track to the tunnel junction.

Beneficially, the conductive layer has a diffusion length greater than 20 nm and, in an embodiment, greater than 100 nm. The greater the diffusion length, the greater the final thickness of the spacer. This long diffusion length also enables a large proportion of the spin current generated by the SOT track to be propagated to the tunnel junction. For example, the conductive layer comprises one material of Cu, Al, Ag, Co, Au or Ni. Alternatively, the conductive layer may comprise a material such as Ti and TiN. The latter have the benefit of being frequently used to form hard masks, so their utilisation is mastered.

Beneficially, the final thickness of the spacer is greater than 10 nm and, in an embodiment, greater than 20 nm. This minimum final thickness guarantees a sufficient distance between the tunnel junction and the top of the spacer to be able to form the SOT track, even with aggressive manufacturing steps, without risking damage to the tunnel junction. It also reduces the risk of migration of a species from the SOT track to the tunnel junction or from the tunnel junction to the SOT track. The greater the final thickness of the spacer, the lower the risk of damage or migration. In addition, a low final thickness may imply a reduced etch rate, limiting the choice of materials for forming the spacer.

Beneficially, the spacer has an etch rate lower than the etch rate of the magnetic stack, the etch rates of the spacer and the magnetic stack being considered for identical etching conditions. In other words, the spacer is harder than the magnetic stack to be etched. Thus, the initial thickness of the spacer does not need to be very great to withstand etching of the magnetic stack. There is therefore less risk of the tunnel junction and the spacer collapsing during their own delimitation. In addition, its shape, and in particular its width or diameter measured in parallel to the substrate, is better controlled when it has a lesser initial thickness. The spacer, in an embodiment, has an etch rate of less than 90% the etch rate of the magnetic stack, or even less than 50% the etch rate of the magnetic stack, and even less than 20% the etch rate of the magnetic stack.

For example, the spacer comprises a hardened alloy of Cu, Al, Ag, Co, Au or Ni, such as AgCd, CuW or CuBr.

Beneficially, the conductive layer is a multilayer. It thus makes it possible to combine spin diffusion or etch rate properties so as to form a spacer with an initial thickness (before etching the magnetic stack) reducing the risk of the spacer and the tunnel junction collapsing during their delimitation. For example, the multilayer alternates a first layer with an etch rate lower than the etch rate of the magnetic stack and a second layer with a diffusion length greater than 20 nm. It thus makes it possible to combine several benefits of different materials. The etch rates of the first and second layers are considered for identical etching conditions.

Beneficially, after delimitation, the first magnetic layer exhibits a perpendicular magnetic anisotropy. Perpendicular means relative to the plane of the layers. The first magnetic layer can also have a perpendicular magnetic anisotropy before delimitation.

Alternatively, after delimitation, the first magnetic layer exhibits a planar magnetic anisotropy. Planar means relative to the plane of the layers.

The magnetic tunnel junction can comprise a second magnetic layer, referred to as a “reference layer”, which, after delimitation, exhibits a fixed magnetisation. According to the aforementioned configuration (free layer in contact with the spacer), the reference layer is disposed between the substrate and the free layer. In other words, the tunnel junction has a so-called “bottom-pinned” configuration. In other words, the reference layer is disposed beneath the free layer, considering the substrate as the lowest. The bottom-pinned configuration offers a benefit when delimiting the tunnel junction by etching. Indeed, etching residues can be deposited onto the walls of the tunnel junction delimited, in the vicinity of the substrate. In the so-called “top-pinned” configuration, the free layer, which is generally not very thick, is located at the level of the substrate. Etching residues can therefore easily short-circuit the tunnel junction. In the bottom-pinned configuration, the reference layer, which is generally thicker, keeps the free layer away from the substrate and reduces the risk of short-circuiting.

Beneficially, the first magnetic layer has a surface state obtained when deposited, the conductive layer being deposited onto the first magnetic layer so as to preserve the surface state of the first magnetic layer. For example, the first magnetic layer and the spacer are consecutively deposited under vacuum, without venting between both deposits. In this way, the surface state of the first magnetic layer is optimal.

Beneficially, forming the SOT track comprises the sub-steps of:
depositing a dielectric layer covering the spacer;
planarising the dielectric layer, with stopping at the top of the spacer;
depositing the SOT track extending partly over the dielectric layer and partly over the spacer.

By “top of an element”, it is meant the highest part of that element, the height being measured perpendicularly to the substrate and from the substrate. The SOT track therefore extends substantially in parallel to the substrate. It extends mainly in a single plane. This configuration provides sufficient spin accumulation on the surface of the SOT track.

Alternatively, forming the SOT track comprises the sub-steps of:
depositing a dielectric layer covering the spacer;
etching a part of the dielectric layer with stopping on the top of the spacer so that the dielectric layer has a flank extending perpendicularly to the substrate, as an extension of a part of a flank of the spacer;
depositing the SOT track extending partly over the dielectric layer and partly over the spacer, the SOT track having two consecutive portions, one of the portions, referred to as a “parallel portion”, extending over the spacer, substantially in parallel to the substrate, and the other of the portions, referred to as a “perpendicular portion”, extending against the flank of the dielectric layer, substantially perpendicularly to the substrate.

By “substantially in parallel” and “substantially parallel”, it is meant parallel to within 20°, or even 10°, and, in an embodiment, to within 5°. Similarly, “substantially perpendicularly” and “substantially perpendicular” are meant to be perpendicular to within 20° or even 10° and, in an embodiment, to within 5°.

Thus, the SOT track is L-shaped, with the perpendicular portion extending in line with the spacer and away from the spacer. It especially has a corner joining the parallel portion with the perpendicular portion. This shape can improve spin diffusion in the spacer.

Alternatively, forming the SOT track comprises the sub-steps of:
placing an insulating layer against the flank of the spacer;
forming a dielectric layer, leaving a portion of the spacer free;
forming a first conductive terminal and a second conductive terminal on the dielectric layer, on either side of the spacer, bearing against the insulating layer, the first and second terminals being distant from each other;
forming the SOT track extending over the spacer by electrically connecting the first and second terminals.

The insulating layer allows the conductive terminals to be placed as close as possible to the spacer, for reducing length of the SOT track.

Beneficially, the first and second terminals are formed so as to create a first wall and a second wall respectively, disposed on either side of the spacer, extending substantially perpendicularly to the substrate and forming a trench with the spacer, the SOT track being deposited into the trench. In this way, the length of the SOT track is extremely limited as it is only located at the spacer. This mode of implementation also makes it easier to align the SOT track with the spacer.

Alternatively, forming the SOT track comprises the complementary substep of flattening the first and second terminals with stopping at the top of the spacer, the SOT track being substantially in parallel to the substrate, partly over the first and second terminals and partly over the spacer. Thus the SOT track is flat and shows sufficient spin accumulation at the spacer.

Beneficially, the SOT track comprises a heavy transition metal such as Pt, Pt/Ti, Ta and β-W, or a topological insulator based on Bi and Sb, and/or Se and/or Te or a so-called “2D” material such as MoS₂ or WS₂ or an Nb-based superconductor.

The invention also relates to a spin-orbit torque effect memory, referred to as an “SOT memory”, comprising, from a substrate:
a magnetic tunnel junction extending over the substrate, comprising a first magnetic layer, referred to as a “free layer”, exhibiting free magnetisation;
a so-called «SOT track “, exhibiting spin-orbit coupling; and
a so-called “spacer” conductive layer, separating the tunnel junction from the SOT track and extending directly against the free layer and directly against the SOT track, the spacer having a spin diffusion length strictly greater than its thickness,
   the memory being remarkable in that the magnetic tunnel junction is “bottom-pinned”.

By “bottom-pinned”, it is meant that the magnetic tunnel junction comprises a second magnetic layer referred to as a “reference layer” having a fixed magnetisation, the reference layer being disposed between the substrate and the free layer.

Beneficially, the tunnel junction and the spacer are delimited by a same flank. By “flank”, it is meant a surface extending perpendicularly to the plane of the layers. Unlike a memory with a funnel shape, as set forth in US 2020/013602 A1, the single flank makes it possible to form a shorter SOT track. Thereby, the resistance of this track is reduced relative to that of prior art.

The invention and its different applications will be better understood upon reading the following description and upon examining the accompanying figures.

### BRIEF DESCRIPTION OF THE FIGURES

The figures are set forth by way of indicating and in no way limiting purposes of the invention. Unless otherwise specified, a same element appearing in different figures has a single reference.

FIG. 1, FIG. 2 and FIG. 3 show three embodiments of a spin-orbit memory of the invention.

FIG. 4, FIG. 5, FIG. 6, FIG. 7, FIG. 8 and FIG. 9 schematically show different steps of a method for manufacturing the spin-orbit memory of FIG. 1.

### DETAILED DESCRIPTION

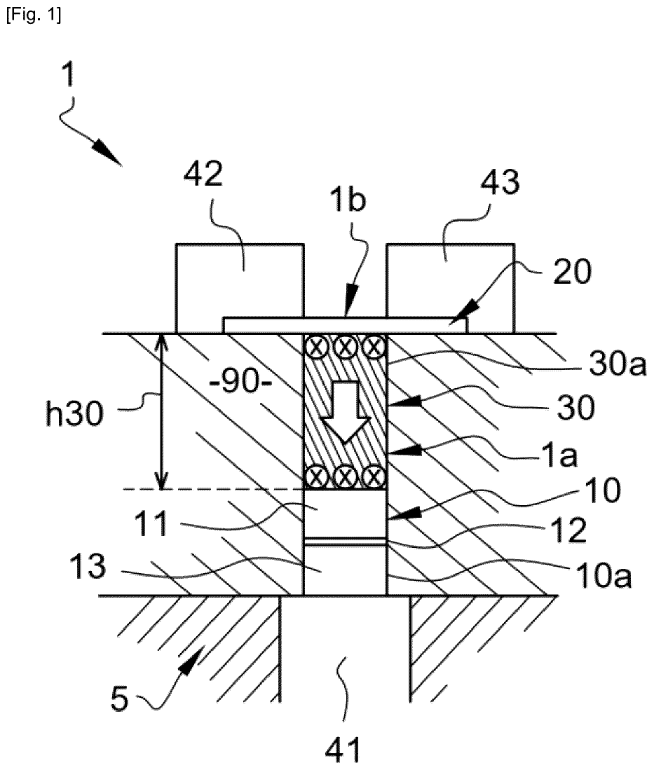

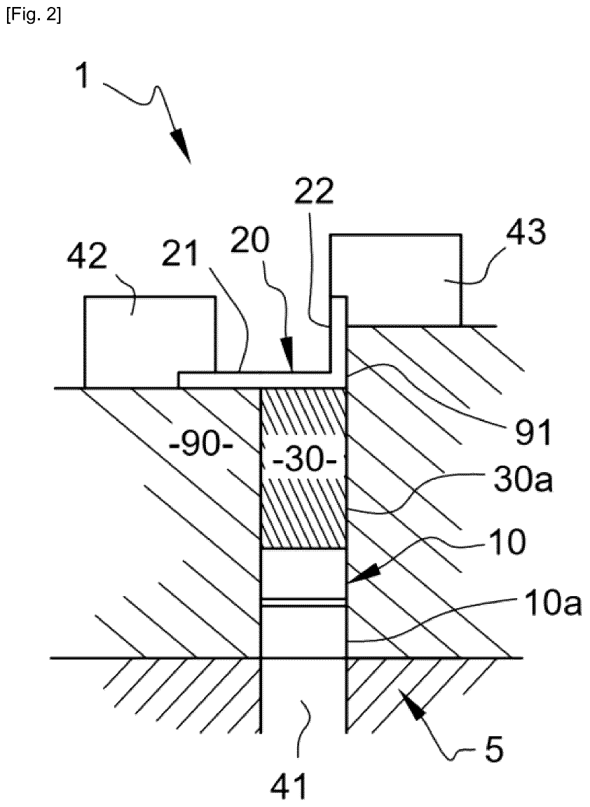

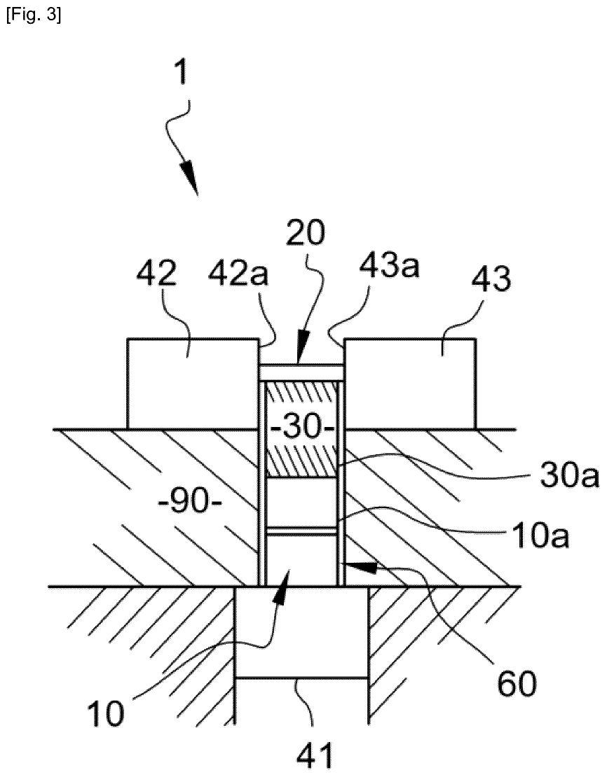

FIG. 1 schematically shows a first embodiment of a spin-orbit torque effect memory 1, i.e. of the SOT type.

In this embodiment, the memory 1 is connected to a first conductive terminal 41. This is, for example, a conductive via passing through a substrate 5 and opening out on the surface thereof. The first terminal 41 may be a conductive via, for example made of copper, responsible for routing in an integrated circuit, for example at a back end of line. Alternatively, the first terminal 41 can be a plug, for example made of tungsten, disposed on the via to block diffusion of species such as copper to the different levels of the back-end of line. Substrate 5 represents, for example, one level of the back-end of line. Substrate 5 is, in an embodiment, non-conductive, for example a semiconductor layer, for example of silicon, covered with one or more dielectric layers, for example of silicon oxide.

The substrate 5, and in particular its surface, defines a reference plane onto which the different layers are deposited. For this reason it is also referred to as a “plane of the layers”. The axis Z extends perpendicularly to the substrate 5. The axis X runs parallel to the substrate 5.

The memory 1 represented in FIG. 1 has two parts 1a, 1b. A first, elongate, part 1a extends along a direction substantially perpendicular to the surface of the substrate 5 (therefore substantially along Z). This first part 1a rests on the first terminal 41. A second part 1b, flattened in shape, extends in a plane substantially parallel to the surface of the substrate 5 (therefore substantially along X). The second part 1b rests on the first part 1a. The memory 1 is T-shaped, resting on the first terminal 41 with which it is electrically connected.

The first part 1a of the memory 1 may be cylindrical, ellipsoidal or parallelepipedal in shape, with its base resting on the first terminal 41. It comprises a magnetic tunnel junction 10 and a so-called “spacer” conductive layer 30. In this example, the conductive layer 30 is non-magnetic.

The magnetic tunnel junction 10 comprises a first magnetic layer 11, referred to as a “free layer”, a second non-magnetic layer 12, referred to as a “tunnel barrier”, and a third magnetic layer 13, referred to as a “reference layer”.

The free layer 11 has a magnetisation and a magnetic anisotropy. The anisotropy of the free layer 11 is configured to stabilise magnetisation according to at least two distinct configurations. For example, the anisotropy of the free layer 11 can spontaneously orient magnetisation out of the plane of the layers. For example, the magnetisation can be oriented substantially perpendicularly to the plane of the layers of the free layer 11. It can then be directed, taking the axis Z in FIG. 1 as a reference, parallel or antiparallel to this axis Z. Anisotropy of the free layer 11 may also be such that the magnetisation spontaneously orients itself in the plane of the free layer 11. Magnetisation can also assume a vortex or skyrmion configuration with a polarity (i.e. a net magnetic moment) out of the plane of the layers.

Said plane of the layers is the plane in which the magnetic layers 11, 13 extend and is considered to be parallel to the substrate.

The free layer 11 can be made from Fe, Co, Ni or an alloy of these elements, for example CoFe, CoFeB or NiFe.

The reference layer 13 also exhibits a so-called “reference magnetisation” and an anisotropy. Anisotropy of the reference layer 13 is, in an embodiment, configured so that the reference magnetisation has a predetermined configuration, for example along a fixed direction and oriented in the plane of the reference layer 13 or oriented out of the plane of this layer 13. Anisotropy of the reference layer is, in an embodiment, such that the reference magnetisation retains its configuration throughout the life or usage time of the memory 1. To achieve this, anisotropy of the reference layer 13 can be enhanced by means of an antiferromagnetic layer (not represented in FIG. 1), coupled to the reference layer 13. This can be a multilayer of ferromagnetic layers coupled together in antiparallel, referred to as a “Synthetic AntiFerromagnetic” or “SAF”.

The reference layer 13 can also be made from Fe, Co, Ni or an alloy of these elements, such as those aforementioned for the free layer 11 and multilayers comprising alternating Co and Pt, for example.

The tunnel barrier 12 is configured to induce a tunnel effect when a spin-polarised current flows in the tunnel junction 10. This current is used, for example, to measure configuration of the magnetisation of the free layer 11 relative to the magnetisation of the reference layer. The tunnel barrier 12 is an insulating, non-magnetic layer. It separates the free layer 11 from the reference layer 13 and extends in contact with these two layers 11, 13. It can be made from oxide, nitride or a combination of oxides and nitrides. For example, it may be MgO, MgAlxOy, AlOx, TiOx, HfOx, TaOx, AlN or ZnO.

The shape of the free layer 11 and the reference layer 13 can contribute to the magnetic anisotropy of these layers by orienting their magnetisations out of the plane of the layers or, on the contrary, in the plane of the layers. The tunnel barrier 12 can also contribute to magnetic anisotropy of the free layer 11 and/or the reference layer. When it consists of MgO, it induces an out-of-plane interfacial anisotropy in contact with CoFe or CoFeB layers. This interfacial anisotropy is beneficially used to orient magnetisation of the free layer 11 out of the plane of the layers.

The tunnel junction 10 may also comprise additional layers not represented in FIG. 1. These are, for example, a seed layer, for favouring a crystalline lattice when the layers forming the tunnel junction 10 grow. It can be made of Ta, Pt, W or MgO.

The spacer 30 is a conductor which rests on the tunnel junction 10. It is as an extension from the tunnel junction 10, substantially perpendicularly to the substrate 5. More particularly, the spacer 30 is in direct contact with the free layer 11. By “direct contact”, it is meant that the spacer 30 and the free layer 11 share a common interface. The spacer 30 comprises at least two faces, opposite to each other. One of both faces of spacer 30 is therefore in direct contact with the free layer 11 of junction 10.

The second part 1b of the memory 1 extends over and in direct contact with the spacer 30. In this example, it also extends over a dielectric layer 90 surrounding the first part 1a. The second part 1b comprises a conductive track 20 referred to as a “SOT track”. This SOT track 20 extends substantially in parallel to the substrate 5. It extends in vertical alignment with the first part 1a and beyond this first part 1a, over the dielectric layer 90.

The SOT track 20 is in direct contact with the spacer 30. For example, it has a face which is in direct contact with one of both faces of the spacer 30, beneficially the one opposite to the face of the spacer 30 in contact with the junction 10. Thus, the spacer 30 separates the junction 10 from the track 30 and makes electrical contact between both of them.

The SOT track 20 is configured so that, when an electric current flows therethrough, it induces a spin current in the spacer 30. The spin current should be distinguished from a spin-polarised electron current. In this case, it is a current that does not involve the displacement of charges but, on the contrary, the flow of a particular polarisation of the spins carried by these charges (the polarisation of the spins being depicted by the circled crosses in FIG. 1). The electric current flowing in the SOT track 20, substantially in parallel to the substrate 5, generates a spin current (depicted by the thick arrow in FIG. 1) propagating in the spacer 30, perpendicularly to the substrate 5, towards the tunnel junction 10.

The SOT track 20 comprises a material exhibiting spin-orbit coupling. This condition can be obtained by means of heavy transition metals such as Pt, β-W, Ta, Hf, Ir, CuBi, Culr or AuW. In this respect, the SOT track 20 is comparable to the SOT tracks of prior art, with the difference that the SOT track 20 according to FIG. 1 extends entirely planar and above the tunnel junction.

The SOT track 20 is connected to two conductive terminals 42, 43 for an electron current to flow.

The generation of a spin current in the spacer 30 is an interfacial phenomenon. The direct contact of the SOT track 20 on the spacer 30 allows generation of the spin current in the spacer 30. It is beneficial that the SOT track 20 and the spacer 30 therefore share a common interface that is large and of good quality for efficiently generating the spin current.

In order to act on magnetisation of the free layer 11 by the SOT effect, the spacer 30 is able to transfer at least some of the spin current induced by the SOT track 20 to the tunnel junction 10 and in particular to the free layer 11. For this, the spacer has a spin diffusion length δ (also referred to as “coherent spin diffusion length”) and a thickness h30 (also referred to as height), measured perpendicularly to the substrate 5 (or, equivalently, to the plane of the layers), such that:

h30<δ

The spin diffusion length corresponds to a length that a spin current can travel in a material before being significantly absorbed. By limiting thickness h30 of the spacer 30 to a value less than the spin diffusion length δ, part of the spin current induced by the SOT track 20 is effectively transferred to the free layer 11 (the spacer 30 being in direct contact with the free layer 11).

The spin current achieves the spin-orbit torque effect (referred to as “SOT”) which can act on magnetisation of the free layer 11. This is an interfacial effect (taking place in the spin diffusion length on either side of the interface). The direct contact of the spacer 30 with the free layer 11 thus enables action of the SOT effect on magnetisation of the free layer 11.

[Table 1] below lists materials as well as their respective diffusion lengths δ. The materials that can be selected to form the spacer 30 beneficially have a diffusion length δ greater than 20 nm. They thus make it possible to form a spacer 30 with a height h30 of up to 20 nm or more.

Materials with a diffusion length δ greater than or equal to 20 nm, or even greater than 50 nm, or even greater than 100 nm, are to be favoured to form the spacer 30. Thus, a large spacer 30 can be formed, up to 20 nm or even 100 nm or more, while still benefiting from a significant SOT effect on magnetisation of the free layer 11.

TABLE 1

| | Spin diffusion length δ |
|---|---|
| Materials | (in nanometres) |
| Al, Cu | 350 |
| Ag | 130 |
| Co | 40 |
| Visit | 32 |
| Ni | 21 |
| Pt, Ru | 14 |
| CoFe | 12 |
| Fe | 8 |
| W | 5 |
| TiN, TaN | 2 |

The spacer 30 makes it possible to space the SOT track 20 apart from the tunnel junction 10 while allowing the propagation of a spin current generated by the SOT track 20. It thus makes it possible to relocate the SOT effect from the SOT track 20. In addition, the spacer 30 also facilitates forming the SOT track 20 while guaranteeing a good quality interface for the action of the SOT effect on magnetisation of the free layer 11. Indeed, the spacer 30 can be formed at the same time as the tunnel junction 10. For example, layers forming the tunnel junction 10 can firstly be deposited and the spacer 30 can secondly be deposited onto these layers. These deposits can beneficially be carried out in a same environment, for example under vacuum. Thus the interface between the tunnel junction 10 and the spacer 30 is protected by the spacer. The surface state of the free layer 11 remains optimal and free of any pollution or particles that could degrade this surface state, whatever the subsequent manufacturing steps.

The SOT effect searched to perform writing to memory 1 occurs at the interface between the free layer 11 and the spacer 30. This interface should therefore be of good quality. On the other hand, the interface between the spacer 30 and the SOT track 20 is much less critical. The face of the spacer 30 on which the SOT track 20 extends can be mechanically and/or chemically polished without this having any significant impact on the writing efficiency. However, it is desirable for the surface roughness to be less than 1 nm RMS.

Since the spacer 30 protects the interface with the free layer 11, it may be contemplated to use materials that are difficult to integrate, or even have a growth incompatibility with a tunnel junction 10 in close proximity thereto, to form the SOT track 20. These may be materials showing topological insulating properties or 2D materials or superconducting materials.

A special feature of spacer 30 according to the invention is that it is placed on the paths used to perform writing to and reading from memory 1. Indeed, it is disposed on the spin current path during writing and on the spin polarised current path passing through junction 10 during reading. The spacer 30 is then beneficially selected to have a high electrical conductivity, beneficially higher than that of the SOT track 20. It is, for example, greater than 10⁶ S/m and, in an embodiment, greater than 107 S/m. For example, considering the SOT track 20 comprised of β-W, spacer 30 can beneficially comprise Ag, Au, Cu, Ni, Co or even α-W.

As the height h30 of the spacer 30 can be parameterised, it can be adjusted to meet manufacturing requirements and especially to make an SOT track 20 which is planar, i.e. substantially parallel to the plane of the layers. However, it is desirable to ensure that the height h30, after manufacture of the memory, is less than the diffusion length δ.

FIG. 2 schematically shows a second embodiment of memory 1. Unlike the embodiment of FIG. 1, the second part 1b, comprising the SOT track 20, does not extend substantially in parallel to the substrate 5. Instead, it is L-shaped. The SOT track 20 has two consecutive portions: a first portion 21, referred to as a “parallel portion”, extending substantially perpendicularly to the substrate 5 and in contact with the spacer 30, and a second portion 22, referred to as a “perpendicular portion”, extending perpendicularly to the substrate 5, as an extension of the flank 30a of the spacer 30. This L shape improves spin diffusion and into the spacer 30.

FIG. 3 schematically shows a third embodiment of memory 1. Unlike the first embodiment of FIG. 1, the second and third terminals 42, 43 come into contact with the first part of memory 1. This reduces the length of the SOT track 20. The first part 1a of memory 1 has an insulating layer 60 on its flank 10a, 30a. By “flank” it is meant a side surface 10a, 30a delimiting the perimeter of memory 1. The purpose of the insulating layer 60 is to electrically insulate the first part 1a of the memory 1 from the second and third terminals 42, 43. These terminals 42, 43 are only connected to the SOT track 20. The insulating layer 60 may cover only a portion of the flank 10a, 30a of the first part 1a. This is at least the flank portion facing the second and third terminals 42, 43. For example, the insulating layer 60 may only cover the flank 30a of the spacer 30.

The insulating layer 60 may be formed by oxidising the flank of the first part 1a of the memory 1. It may also be formed by conformally depositing a dielectric or by conformally depositing a semiconductor which is subsequently oxidised. However, it is desirable to protect the upper surface of the spacer 30 if the insulating layer 60 is formed before the SOT track. Alternatively, the insulating layer 60 is formed after forming the SOT track.

In the example illustrated by FIG. 3, the second and third terminals 42, 43, pressed against the spacer 30 (and herein against the insulating layer 60), form a cavity at the bottom of which the SOT track 20 extends, connecting both terminals. Each of the terminals 42, 43 has a wall 42a, 43a extending as an extension of the flank 30a of the spacer 30. These walls 42a, 43a thus form the walls of the trench. Alternatively, both terminals 42, 43 can be disposed on either side of the first part 1a of the memory 1, flush with the spacer 30. The SOT track 20 then extends in a planar manner over both terminals 42, 43 and the top of the spacer 30.

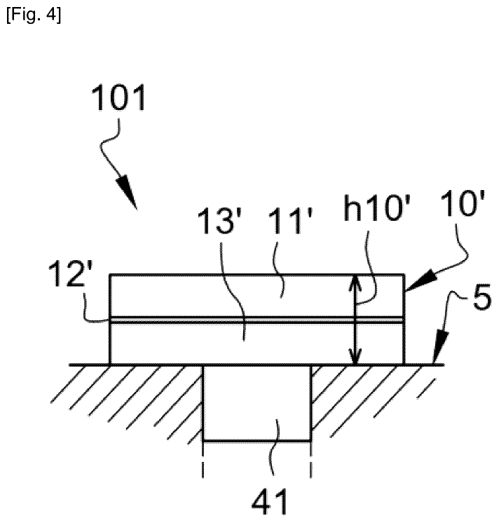

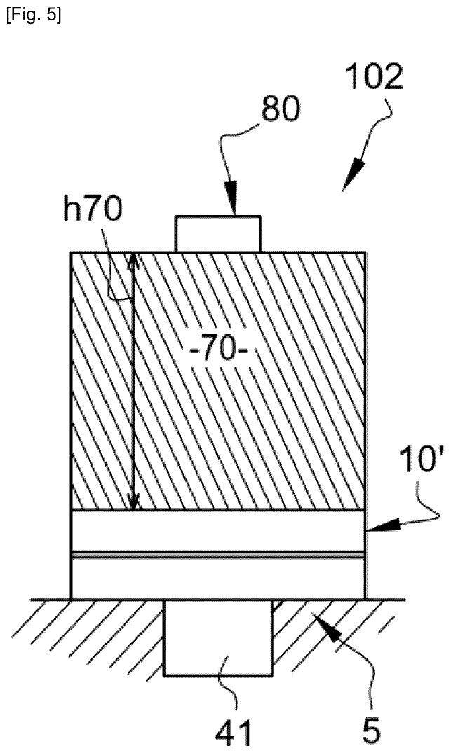

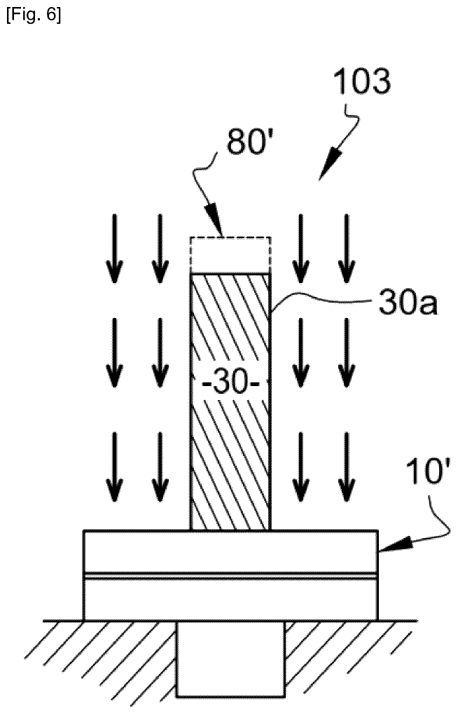

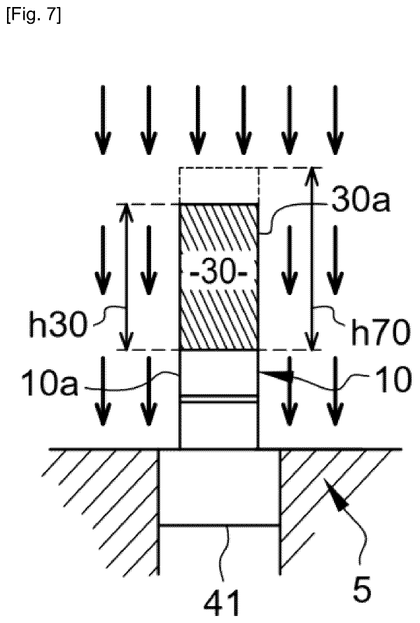

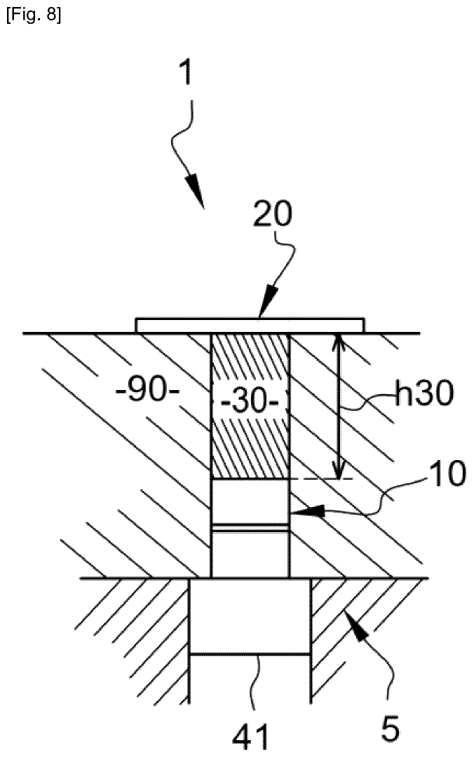

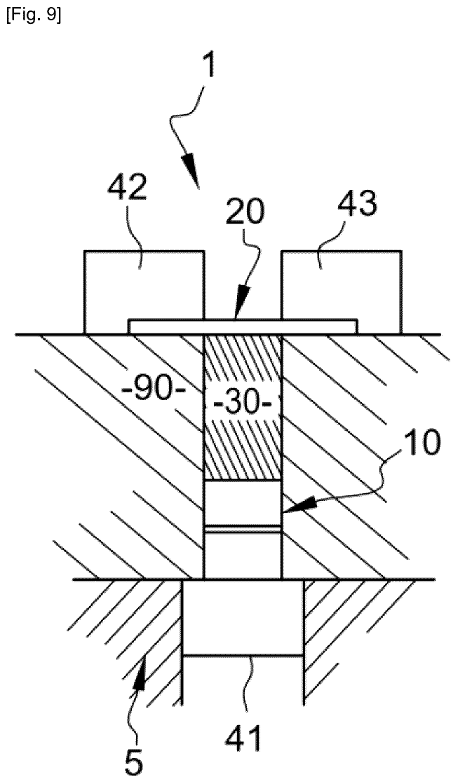

FIGS. 4 to 9 schematically show a mode of implementation of a manufacturing method for obtaining the memory 1 shown in FIG. 1. The manufacturing method can be carried out from a substrate 5, as set forth in FIG. 4, extending in a plane coincident with a so-called “plane of the layers” parallel to the substrate 5. The substrate 5 is made of Si, for example. In this mode of implementation, a first terminal 41 partly passes through the substrate 5 and opens onto its surface via an aperture. The top of the first terminal 41 is flush with the surface of the substrate 5. The first terminal 41 may be a via, a “BEOL” (Back End Of Line) type plug or a track extending partly into the substrate 5.

A first step in the method, illustrated by FIG. 4, consists in depositing 101 a magnetic stack 10′ onto the substrate 5. This stack comprises first, second and third layers 11, 12, 13 which are for forming the layers 11, 12, 13 of the tunnel junction 10. This depositing 101 comprises, for example, depositing two magnetic layers 11′, 13′ separated by an insulating layer 12′. The first magnetic layer 11′ is, for example, for forming, once delimited, the free layer 11 of the tunnel junction 10. The method may also comprise initially depositing layers for forming a seed layer and/or a synthetic antiferromagnet (not represented in this figure), as previously discussed.

The method then comprises depositing 102 a conductive layer for forming the spacer 30, illustrated in FIG. 5. The conductive layer 70 comprises, for example, a material offering a great spin diffusion length, as discussed above. It is for example Cu. The conductive layer 70 is directly deposited into contact with the magnetic stack 10′ and more particularly with the first magnetic layer 11′. Depositing 102 is carried out, for example, by means of a physical deposition method. Other deposition methods may be contemplated, such as chemical deposition.

The stack 10′ and the conductive layer 70 are beneficially deposited in two successive steps. Thus, the surface state of the first, freshly deposited, magnetic layer 11′ can be protected by the conductive layer 70. The atmosphere in which these different layers are deposited is, in an embodiment, maintained. For example, the depositions are made in a vacuum or in an atmosphere of neutral gas, with no venting between depositions. Thus, quality of the surface state of the first magnetic layer 11′ is preserved and protected by the conductive layer 70. This deposition thus guarantees a very good quality interface between the free layer 11 of the tunnel junction 10 and the spacer 30.

The method may comprise annealing, carried out after depositing 101 the magnetic stack 10′ and the conductive layer 70. For example, when the first magnetic layer 11′ of the stack 10′ is made of CoFeB and the insulating layer 12′ is made of MgO, annealing improves the interface between these two layers and increases the out-of-plane magnetic anisotropy between these two layers 11′, 12′. This can result in a free layer 11 with perpendicular anisotropy after delimiting the junction. Annealing can also improve interface between the first magnetic layer 11′ and the conductive layer 70. Annealing can also be carried out after etching the conductive layer 70 and the magnetic stack 10′.

The conductive layer 70 is deposited with a first thickness h70, measured perpendicularly to the substrate 5, referred to as a “initial thickness” or “initial height”. It depends on the etch rate of the material used to form this layer 70 as well as the etch rate of the magnetic stack 10′. Generally speaking, by “etch rate”, it is meant the rate at which a layer is etched. This etch rate is assessed under reproducible etching conditions. The comparison between two etch rates is therefore made for identical etching conditions. Indeed, the etch rate is highly dependent on the species used as the etching element or on the composition of the fluids or gases used to carry out etching. In addition, as the magnetic stack 10′ may comprise layers with different etch rates, the etch rate considered is the mean rate of the etch rates of the layers in the stack 10′.

FIG. 6 sets forth a step 103 of delimiting the conductive layer 70 so as to form the spacer 30. This delimitation is achieved by anisotropic etching through a first mask 80, for example made of resin. Etching 103 is stopped on the stack 10′. The mask 80, for example of resin, is formed by photolithography on the spacer 30. The initial thickness h70 of the conductive layer 70 is maintained during the delimitation step 103. It is therefore not equal to but on the contrary greater than the final thickness h30 of the spacer 30 as set forth in FIG. 1.

Etching 103 the spacer 30 can be aligned with the first terminal 41 so that the resulting memory 1 is connected to this terminal 41.

FIG. 7 sets forth a step 104 of delimiting the magnetic stack 10′ so as to form the tunnel junction 10. This delimitation 104 is achieved by anisotropic etching through a second mask. Etching is stopped on the substrate 5. In this example, etching is carried out using the spacer 30 as a second etching mask. The stack 10′ is thus etched as an extension of the spacer 30. Etching is carried out while maintaining a very good quality interface between the first magnetic layer 11′ (now forming the free layer 11) and the spacer 30.

At the end of the step 104 of delimiting the tunnel junction 10, the spacer 30 has its final thickness h30. When it is used as an etching mask, its initial thickness h70 is beneficially selected so that it has a final thickness h30 at the end of etching for performing writing by the SOT effect. Its initial thickness h70 depends on the etch rate v30 of the conductive layer 70, as well as the etch rate v10′ and the height h10′ of the stack 10′. The initial thickness h70 is, for example, substantially equal to:

$$h 70 \approx h {10}^{′} \times v 30 / v {10}^{′} + h 30$$

By “substantially equal” or by the sign ‘≈’, it is meant equal to within 20%, or even 10%.

Since the thickness h30 of the spacer 30 has to be less than the diffusion length δ to allow the SOT effect, the initial thickness h70 of the conductive layer is, in an embodiment, less than:

$$h 70 < h {10}^{′} \times v 30 / v {10}^{′} + δ$$

FIG. 8 schematically sets forth forming 105 the SOT track 20. It first comprises a sub-step of depositing a dielectric layer 90 flush with the top of the spacer 30 (i.e. the free part of the spacer 30). This dielectric layer 90 is deposited, for example, by covering the junction 10 and the spacer 30. Then the mechanical and/or chemical polishing, stopping at the top of the spacer 30 releases the same from the dielectric layer 90. The dielectric layer 90 comprises, for example, SiO₂. A sub-step of depositing the material for forming the SOT track 20, for example a heavy transition metal or a 2D material or a topological insulator or a superconducting material, is deposited onto the spacer 30 and the dielectric layer 90. The deposition is made through a mask or the layer is etched through a mask, or the material may be transferred to form the SOT track 20. The SOT track 20 extends flat (i.e. substantially parallel to the substrate 5), partly against the spacer 30 and partly over the dielectric layer 90.

FIG. 9 schematically sets forth forming 10⁶ the second and third terminals 42, 43. They are obtained by depositing a metal through a mask so that they each connect one end of the SOT track 20. The second and third terminals 42, 43 can also take the form of vias rising from the substrate 5 to the SOT track 20.

To form the memory 1 of FIG. 2, the step of forming the SOT track 20 differs from the step illustrated by FIG. 8 in that the dielectric layer 90 is not flattened by polishing. Instead, it has a difference in height on either side of the first part 1a of memory 1. On one side of the first part 1a only, the dielectric layer 90 has a greater height than the spacer 30. The dielectric layer 90 thus provides a surface, extending as an extension of the flank of the first part 1a, over which the second portion 22 of the SOT track 20 can extend. The difference in height of the dielectric layer 90 is obtained by etching, for example. Etching is carried out in such a way as to form a flank 91 of the dielectric layer 90 which extends as an extension of the flank 30a of the spacer 30. The SOT track 20 can then be made by conformal deposition against the spacer 30 and the flank 91 perpendicular to the substrate 5.

To form the memory 1 of FIG. 3, the steps of forming the SOT track 20 and for forming the second and third terminals 42, 43 are modified and reversed.

Firstly, the manufacturing method comprises an additional step of forming the insulating layer 60 on the flank 10a, 30a of the tunnel junction 10 and the spacer 30. This insulating layer 60 is obtained, for example, by conformally depositing an oxide film. It can also be obtained by conformally depositing a semiconductor film which is secondly thermally oxidised. Anisotropic etching or chemical and physical planarisation of this conformal film enables the upper face of the spacer 30 to be cleared.

Secondly, the first sub-step of forming 105 the SOT track 20, which consists in depositing the dielectric layer 90, is carried out so as to only clear a portion of the height of the first part 1a.

The second and third terminals 42, 43 are then formed on either side of the spacer 30, bearing against the insulating layer 60. The terminals 42, 43 are formed so as to protrude beyond the spacer 30. In other words, they form the walls 52a, 43a of a trench of which the spacer 30 is the bottom. Finally, the second sub-step of forming 105 the SOT track 20 consisting in depositing the material for forming the SOT track 20 (for example Pt or Nb) is carried out in the cavity formed by the terminals 42, 43.

Alternatively, when the second and third terminals are formed at the height of the spacer 30, i.e. flush with the top of the spacer 30 on the spacer 30 and the dielectric layer 90. The deposition of the SOT track 20 makes it possible to obtain a track substantially parallel to the plane of the layers.

Expressions such as “comprise”, “include”, “incorporate”, “contain”, “is” and “have” are to be construed in a non-exclusive manner when interpreting the description and its associated claims, namely construed to allow for other items or components which are not explicitly defined also to be present. Reference to the singular is also to be construed in be a reference to the plural and vice versa.

The articles “a” and “an” may be employed in connection with various elements and components of compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

As used herein in the specification and in the claims, the phrase “at least one”, in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

A person skilled in the art will readily appreciate that various features, elements, aspects, parameters disclosed in the description may be modified and that various embodiments disclosed may be combined without departing from the scope of the invention. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Having described above several aspects of at least one embodiment, it is to be appreciated various alterations, modifications, and improvements will readily occur to those skilled in the art. Such alterations, modifications, and improvements are intended to be aspects of this disclosure. Accordingly, the foregoing description and drawings are by way of example only.

The invention claimed is:

1. A method for manufacturing a spin-orbit torque memory, forming an SOT memory, comprising, starting from a substrate:
depositing a magnetic stack for forming, after delimitation, a magnetic tunnel junction, the magnetic stack comprising a first magnetic layer exhibiting, after delimitation, a free magnetisation;
depositing a conductive layer onto the magnetic stack and directly against the first magnetic layer, the conductive layer having a spin diffusion length;
anisotropically etching a spacer into the conductive layer through a first etching mask with stopping on the magnetic stack;
etching the magnetic stack so as to delimit the magnetic tunnel junction, etching being carried out anisotropically employing the spacer as a second etching mask, the spacer exhibiting, after etching, a final thickness less than its spin diffusion length; and
forming, on the spacer and directly against this spacer, a SOT track, from a material exhibiting spin-orbit coupling;
the conductive layer has an initial thickness h70 given by:
h70<h10′×v30/v10′+δ
where h10′ is the thickness of the magnetic stack), v10′ is an etch rate of the magnetic stack, v30 is an etch rate of the conductive layer and δ is a spin diffusion length of the conductive layer, the etch rates of the magnetic stack and the conductive layer being considered for identical etching conditions.

2. The method according to claim 1, wherein the conductive layer has a spin diffusion length greater than 20 nm.

3. The method according to claim 2, wherein the conductive layer comprises one material of Cu, Al, Ag, Co, Au or Ni.

4. The method according to claim 1, wherein the spacer has a final thickness greater than 10 nm.

5. The method according to claim 1, wherein the spacer has an etch rate lower than the etch rate of the magnetic stack, the etch rates of the spacer and of the magnetic stack being considered for identical etching conditions.

6. The method according to claim 5, wherein the spacer comprises a hardened alloy of Cu, Al, Ag, Co, Au or Ni, such as AgCd, CuW or CuBr.

7. The method according to claim 1, wherein the conductive layer is a multilayer.

8. The method according to claim 7, wherein the multilayer alternates a first layer having an etch rate lower than the etch rate of the magnetic stack and a second layer having a spin diffusion length greater than 20 nm, the etch rates of the first and second layers being considered for identical etching conditions.

9. The method according to claim 1, wherein the first magnetic layer exhibits, after delimitation, a perpendicular magnetic anisotropy.

10. The method according to claim 1, wherein forming the SOT track comprises the sub-steps of:
depositing a dielectric layer covering the spacer;
flattening the dielectric layer, stopping at the top of the spacer;
depositing the SOT track extending partly over the dielectric layer and partly over the spacer.

11. The method according to claim 1, wherein forming the SOT track comprises the sub-steps of:
depositing a dielectric layer covering the spacer;
etching a part of the dielectric layer with stopping on the top of the spacer so that the dielectric layer has a flank extending perpendicularly to the substrate, as an extension of a part of a flank of the spacer;
depositing the SOT track extending partly over the dielectric layer and partly over the spacer, the SOT track having two consecutive portions, one of the portions, forming a parallel portion, extending over the spacer, substantially in parallel to the substrate, and the other of the portions, forming a perpendicular portion, extending against the flank of the dielectric layer, substantially perpendicularly to the substrate.

12. The method according to claim 1, wherein forming the SOT track comprises the sub-steps of:
depositing an insulating layer against the side of the spacer;
forming a dielectric layer leaving a portion of the spacer free;
forming a first conductive terminal and a second conductive terminal on the dielectric layer, on either side of the spacer, resting against the insulating layer, the first and second terminals being distant from each other;
forming the SOT track extending over the spacer by electrically connecting the first and second terminals.

13. The method according to claim 12, wherein the first and second terminals are formed so as to create a first wall and a second wall respectively, disposed on either side of the spacer, extending substantially perpendicularly to the substrate and forming a trench with the spacer, the SOT track being deposited into the trench.

14. The method according to claim 12, wherein forming the SOT track comprises the complementary sub-step of flattening the first and second terminals with stopping at the top of the spacer, the SOT track being substantially parallel to the substrate, partly over the first and second terminals and partly over the spacer.

15. A spin-orbit torque effect memory, forming a SOT memory, comprising, from a substrate:
a magnetic tunnel junction extending over the substrate, comprising a first magnetic layer, forming a free layer, exhibiting free magnetisation;
a track, forming a SOT track, exhibiting spin-orbit coupling; and
a conductive layer, forming a spacer, separating the tunnel junction from the SOT track and extending directly against the free layer and directly against the SOT track, the spacer having a spin diffusion length strictly greater than its thickness,
wherein the magnetic tunnel junction is bottom-pinned and the spacer has a final thickness greater than 10 nm.
